(19) United States
(12) Patent Application Publication
(10) Pub. No.: US 2026/0238191 A1
(43) Pub. Date: Aug. 13, 2026

(54) FILTER CIRCUIT AND ADJUSTABLE INDUCTOR THEREOF

(71) Applicant: REALTEK SEMICONDUCTOR CORP., HsinChu (TW)

(72) Inventors: Wei-Ting Bai, HsinChu (TW); Chia-Jun Chang, HsinChu (TW); Ping-Hsuan Tsai, HsinChu (TW)

(73) Assignee: REALTEK SEMICONDUCTOR CORP., HsinChu (TW)

(21) Appl. No.: 19/532,475

(22) Filed: Feb. 6, 2026

(30) Foreign Application Priority Data
Feb. 8, 2025 (TW) 114104770

(51) Int. Cl. H03H 11/04

(52) U.S. Cl. CPC H03H 11/04

(57) ABSTRACT

A filter circuit and adjustable inductor thereof is related to a filter circuit including a power terminal, an output terminal, a power wiring, and an adjustable inductor. The power terminal is configured to receive an operation power. The output terminal is configured to output the operation power. The power wiring is coupled between the power terminal and the output terminal. The adjustable inductor is electrically connected between the power wiring and a ground terminal, and the adjustable inductor is configured to eliminate noise on the power wiring. The adjustable inductor includes a first transductor and a second transductor. The first transductor and the second transductor have inverted transconductance phases, and the second transductor is electrically connected between two ends of the first transductor.

### CROSS-REFERENCE TO RELATED APPLICATION

This non-provisional application claims priority under 35 U.S.C. § 119(a) to Patent Application No. 114104770 filed in Taiwan, R.O.C. on Feb. 8, 2025, the entire contents of which are hereby incorporated by reference.

### BACKGROUND

### Technical Field

The instant disclosure relates to a filter and an inductor thereof, in particular to a filter circuit and an adjustable inductor thereof.

### Related Art

In various types of circuit systems (for example, but not limited to, analog system digital systems, and radio-frequency systems), a wiring of a power source is often interfered by other paths, and therefore noise is generated. As a result, an operation of the circuit system is affected. In order to overcome various types of noises that may exist in the circuit system, a filter is applied in the circuit system to adjust a frequency response. In general, a filter known to the inventor consists of inductors and capacitors connected to each other in series/parallel. However, an area of the filter known to the inventor is too large, so that the filter known to the inventor has the problem of high cost. In addition, an inductance of the inductor in the filter known to the inventor cannot be adjusted, so that the filter known to the inventor has the problem of low quality factor.

### SUMMARY

In view of this, a filter circuit and adjustable inductor thereof is applied to effectively adjust inductance of the adjustable inductor, and simultaneously solve the problems such as floor-planning area being too large, insufficient quality factor (also called as “Q value”).

In some embodiments, a filter circuit includes a power terminal, an output terminal, a power wiring, and an adjustable inductor. The power terminal is configured to receive an operation power. The output terminal is configured to output the operation power. The power wiring is coupled between the power terminal and the output terminal. The adjustable inductor is electrically connected between the power wiring and a ground terminal, and the adjustable inductor is configured to eliminate noise on the power wiring.

In some embodiments, the adjustable inductor includes a first transductor and a second transductor. An input terminal of the first transductor is electrically connected to the power terminal. An output terminal of the second transductor is electrically connected to the input terminal of the first transductor, and an input terminal of the second transductor is electrically connected to an output terminal of the first transductor.

In some embodiments, the first transductor includes a first transistor and a first current source, the first current source is electrically connected between a first power source and a node, an input terminal of the first transistor is electrically connected to the node, a control terminal of the first transistor is electrically connected to the power terminal, and an output terminal of the first transistor is electrically connected to the ground terminal. The second transductor includes a second transistor and a second current source, an input terminal of the second transistor is electrically connected to a second power source, a control terminal of the second transistor is electrically connected to the node, an output terminal of the second transistor is electrically connected to the power terminal, and the second current source is electrically connected between the power terminal and the ground terminal.

In some embodiments, the first transistor is an adjustable transistor, and/or the second transistor is another adjustable transistor.

In some embodiments, the first transistor is single transistor element, and/or the second transistor is another single transistor element.

In some embodiments, a voltage value of the first power source and a voltage value of the second power source are both less than a voltage value of the operation power.

In some embodiments, the first transductor further includes a resistor and a third transistor. The resistor is electrically connected between the node and the control terminal of the second transistor. An input terminal of the third transistor is electrically connected to the node, a control terminal of the third transistor is electrically connected to an offset voltage, and an output terminal of the third transistor is electrically connected to the input terminal of the first transistor.

In some embodiments, the third transistor is an adjustable transistor.

In some embodiments, the third transistor is single transistor element.

In some embodiments, the filter circuit further includes an impedance element. The impedance element is connected to the adjustable inductor in parallel.

In some embodiments, the filter circuit further includes an impedance element. One of two ends of the impedance element is electrically connected to the power terminal, and the other end of the impedance element is electrically connected to the adjustable inductor.

In some embodiments, the filter circuit further includes an impedance element. One of two ends of the impedance element is electrically connected to the power wiring, and the other end of the impedance element is electrically connected to the adjustable inductor and the output terminal.

In alternative embodiments, an adjustable inductor includes a first transductor and a second transductor. The first transductor and the second transductor have inverted transconductance phases. The second transductor is electrically connected between two ends of the first transductor.

As above, according to any embodiment, the filter circuit or the adjustable inductor is able to implement an inductor having adjustment function of inductance (i.e., an adjustable inductor) through a small number of hardware elements. According to one or some embodiments, the filter circuit is able to effectively eliminate noise which is from an external power source and received by a circuit system through the adjustable inductor, thereby improving the stability of the circuit system. In addition, through changing a parameter of each hardware element in the adjustable inductor, the cost, size, and power consumption of the adjustable inductor can be effectively reduced, such that the quality factor of the adjustable inductor is increased. Furthermore, according to some embodiments, depending on configuration position of the impedance element the impedance element and the adjustable inductor can form the filter circuits with different circuit combinations, thereby implementing various types of filters.

### BRIEF DESCRIPTION OF THE DRAWINGS

The instant disclosure will become more fully understood from the detailed description given herein below for illustration only, and therefore not limitative of the instant disclosure, wherein:

FIG. 1A illustrates a schematic diagram of an embodiment of an adjustable inductor.

FIG. 1B illustrates a schematic diagram of a first exemplary embodiment of an adjustable inductor.

FIG. 2 illustrates a circuit diagram of a second exemplary embodiment of the adjustable inductor in FIG. 1A.

FIG. 3 illustrates a circuit diagram of a third exemplary embodiment of the adjustable inductor in FIG. 1A.

FIG. 4 illustrates a circuit diagram of a fourth exemplary embodiment of the adjustable inductor in FIG. 1A.

FIG. 5 illustrates a circuit diagram of a fifth exemplary embodiment of the adjustable inductor in FIG. 1A.

FIG. 6 illustrates a schematic diagram of a first embodiment of a filter circuit.

FIG. 7 illustrates a schematic diagram of a second embodiment of a filter circuit.

FIG. 8 illustrates a schematic diagram of a third embodiment of a filter circuit.

FIG. 9 illustrates a schematic diagram of a fourth embodiment of a filter circuit.

FIG. 10 illustrates a schematic diagram of an embodiment of an adjustable transistor.

### DETAILED DESCRIPTION

In view of the terms used in this specification, it should be clear that the term “including” is an open term, and therefore should be interpreted as “including but not limited to”. The term such as “coupling” or “electrical connection” means that two or more components are in physical or electrical contact with each other “directly”, or in physical or electrical contact with each other indirectly. Terms “one”, “another”, “first”, “second”, and “third” are used to distinguish the referred components, and unless otherwise specified, are not used to order or limit the differences of the referred components, nor are they used to limit the scope of the present disclosure.

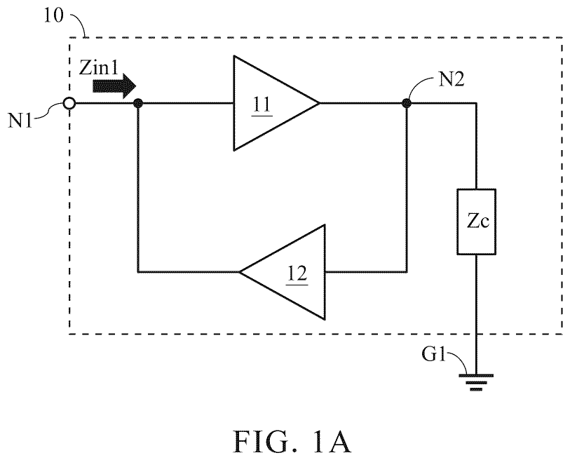

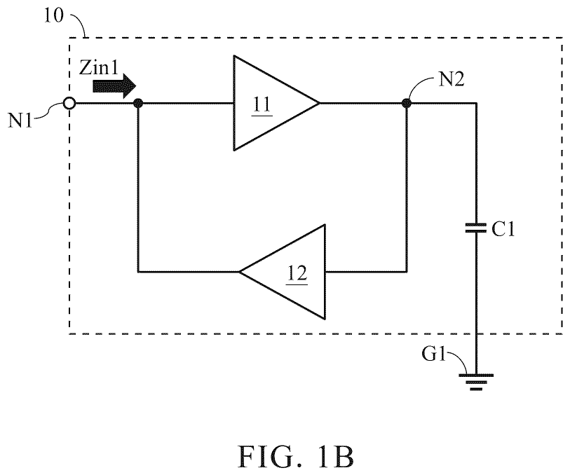

Refer to FIG. 1A. An adjustable inductor 10 includes two transductors 11, 12 (hereinafter respectively called as a first transductor 11 and a second transductor 12). The first transductor 11 and the second transductor 12 have inverted transconductance phases. In an embodiment, the first transductor 11 has positive transconductance, and the second transductor 12 has negative transconductance. In another embodiment, the first transductor 11 has negative transconductance, and the second transductor 12 has positive transconductance.

The second transductor 12 is electrically connected between two ends of the first transductor 11. In some embodiments, the output terminal of the second transductor 12 is electrically connected to the input terminal of the first transductor 11, the input terminal of the second transductor 12 is electrically connected to the output terminal of the first transductor 11.

In this embodiment, the input terminal of the first transductor 11 and the output terminal of the second transductor 12 are coupled to each other at a node N1 (hereinafter called as a first node N1), and the output terminal of the first transductor 11 and the input terminal of the second transductor 12 are coupled to each other at another node N2 (hereinafter called as a second node N2). In other words, the first node N1, the input terminal of the first transductor 11, and the output terminal of the second transductor 12 have identical voltage values (i.e., electric potential of their equivalent circuit is equal), and the second node N2, the output terminal of the first transductor 11, and the input terminal of the second transductor 12 have identical the voltage values.

An output terminal of the adjustable inductor 10 (i.e., the second node N2) has a capacitive impedance Zc (i.e., output impedance of the adjustable inductor 10). This capacitive impedance Zc is between the second node N2 and the ground terminal G1. Through the inverted transconductance phases of the first transductor 11 and the second transductor 12, the capacitive impedance Zc of the output terminal can be converted into the inductive impedance of the input terminal (i.e., the input impedance Zin1 of the adjustable inductor 10). In other words, the input impedance Zin1 of the input terminal of the adjustable inductor 10 (i.e., the first node N1) appears inductivity, as presented in Equation 1.

$$Zin 1 = j ω L \qquad Equation 1$$

The term “L” represents the inductance of the adjustable inductor 10, whose unit is Henry (H). The term “j” represents an imaginary unit. The term “ω” represents the angular frequency of the electrical signal passing through the adjustable inductor 10 (i.e., it is 2π times the frequency of the electrical signal), whose unit is arc/sec.

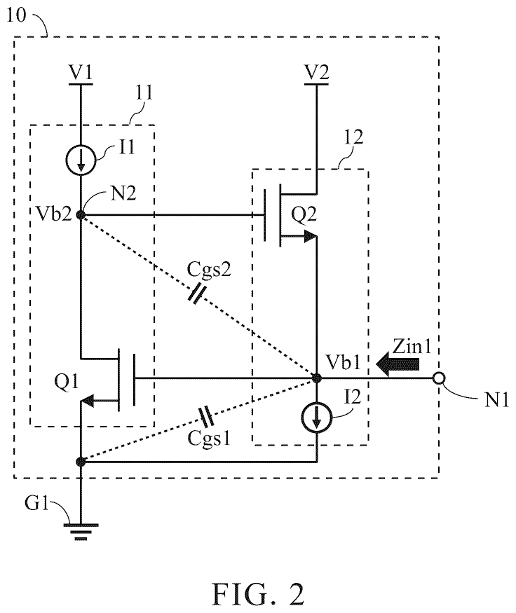

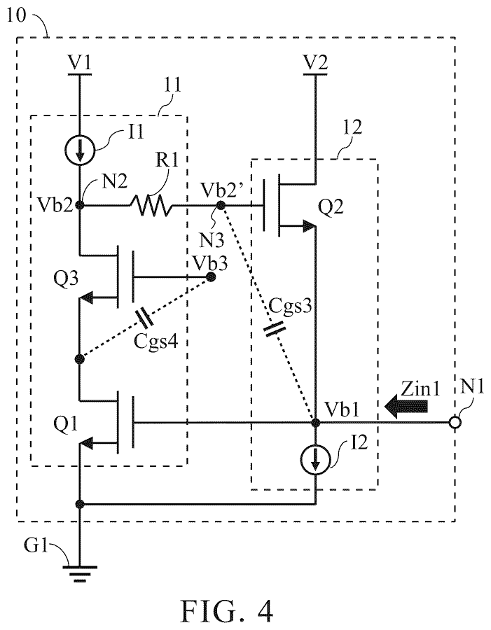

In some embodiments, the impedance element which provides this capacitive impedance Zc may be a capacitor element C1 which is actively added; i.e., this capacitor element C1 is a component other than the transductors 11, 12 and is coupled between the second node N2 and the ground terminal G1, as shown in FIG. 1B. In alternative embodiments, the impedance element which provides this capacitive impedance Zc may be parasitic capacitor(s) of one or more elements which constitutes the transductors 11, 12 (for example, the parasitic capacitors Cgs1, Cgs2 within the transductors 11, 12 shown in FIG. 2 or the parasitic capacitors Cgs3, Cgs4 within the transductors 11, 12 shown in FIG. 4).

Refer to FIG. 1A and FIG. 2. In some embodiments, each transductor 11/12 includes a transistor Q1 or Q2) and a current source I1 (or I2). Specifically, the first transductor 11 includes the transistor Q1 (hereinafter called as a first transistor Q1) and the current source I1 (hereinafter called as a first current source I1), and the second transductor 12 includes another transistor Q2 (hereinafter called as a second transistor Q2) and another current source I2 (hereinafter called as a second current source I2). Herein, the first current source I1 and the second current source I2 may be fixed current sources having fixed current values or may be variable current sources having an adjustment function of current value.

As shown in FIG. 2, in some embodiments, the first current source I1 is electrically connected between a power source V1 (hereinafter called as a first power source V1) and the second node N2. In other words, one of two ends of the first current source I1 is electrically connected to the first power source V1, and the other end of the first current source I1 is electrically connected to the second node N2. In some embodiments, the input terminal of the first transistor Q1 is electrically connected to the second node N2, the control terminal of the first transistor Q1 is electrically connected to the first node N1, and the output terminal of the first transistor Q1 is electrically connected to a ground terminal G1. In other words, the input terminal of the first transistor Q1 is electrically connected to the other end of the first current source I1.

As shown in FIG. 2, in some embodiments, the input terminal of the second transistor Q2 is electrically connected to another power source V2 (hereinafter called as a second power source V2), the control terminal of the second transistor Q2 is electrically connected to the second node N2, and the output terminal of the second transistor Q2 is electrically connected to the first node N1. In other words, the control terminal of the second transistor Q2 is electrically connected to the input terminal of the first transistor Q1 and the other end of the first current source I1, and the output terminal of the second transistor Q2 is electrically connected to the control terminal of the first transistor Q1. In some embodiments, the second current source I2 is electrically connected between the first node N1 and a ground terminal G1. In other words, one of two ends of the second current source I2 is electrically connected to the control terminal of the first transistor Q1 and the output terminal of the second transistor Q2, and the other end of the second current source I2 is electrically connected to the ground terminal G1. The control terminal of the first transistor Q1 is configured to receive an offset voltage Vb1 (i.e., the terminal voltage of the first node N1), such that working region of the first transistor Q1 is decided by the offset voltage Vb1. The control terminal of the second transistor Q2 is configured to receive an offset voltage Vb2 (i.e., the terminal voltage of the second node N2), such that working region of the second transistor Q2 is decided by the offset voltage Vb2.

It should be noted that the capacitive impedance Zc shown in FIG. 1A may be provided by the parasitic capacitor Cgs1 of the first transistor Q1 and the parasitic capacitor Cgs2 of the second transistor Q2 shown in FIG. 2. In other words, the output terminal of the adjustable inductor 10 has the capacitive impedance Zc because of the parasitic capacitors Cgs1, Cgs2. And, through the positive and negative transconductances of the first transductor 11 and the second transductor 12, the capacitive impedance Zc can be converted into the input impedance Zin appearing inductivity of the input terminal of the adjustable inductor 10. That is, the first transistor Q1, the second transistor Q2, the first current source I1, and the second current source I2 are related to the value of the input impedance Zin1. Specifically, the value of the input impedance Zin1 changes along with any change in the working region of the first transistor Q1, the working region of the second transistor Q2, the current amplitude of the first current source I1, and the current amplitude of the second current source I2. In other words, the user is able to change the value of the input impedance Zin1 of the adjustable inductor 10 through adjusting at least one of the offset voltage of the first transistor Q1, the offset voltage of the second transistor Q2, the current value of the first current source I1, and the current value of the second current source I2. As a result, the inductance can be effectively adjusted.

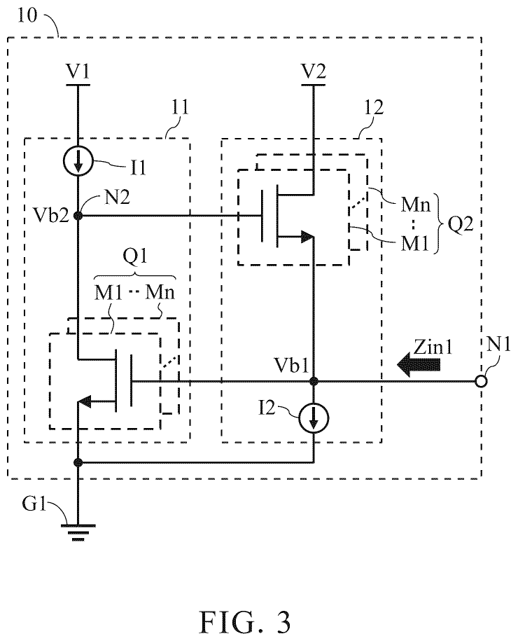

In some embodiments, the first transistor Q1 may be single transistor element, and/or the second transistor Q2 may be another single transistor element, as shown in FIG. 2. In alternative embodiments, the first transistor Q1 may be an adjustable transistor, and/or the second transistor Q2 may be another adjustable transistor. Taking FIG. 3 as an example, the first transistor Q1 and/or the second transistor Q2 may be adjustable transistor(s) implemented by n transistor elements M1-Mn, wherein n is a positive integer greater than 1. In this case, the value of the input impedance Zin1 is related to a size of the first transistor Q1 and/or a size of the second transistor Q2. At this time, the user can change the value of the input impedance Zin1 of the adjustable inductor 10 through adjusting the number of the transistor elements M1-Mn used for the first transistor Q1 and/or the second transistor Q2. In some embodiments, when the first transistor Q1 and the second transistor Q2 are adjustable transistors, these adjustable transistors may be implemented by identical number of transistor elements M1-Mn (i.e., K1 =K2) or may be implemented by different numbers of transistor elements M1-Mn (i.e., K1 ≠K2). Herein, a total number (n) of the transistor elements M1-Mn of the first transistor Q1 is K1 , and a total number (n) of the transistor elements M1-Mn of the second transistor Q2 is K2. K1 and K2 are both positive integers.

It should be understood that FIG. 2 illustrates that the first transistor Q1 and the second transistor Q2 both are single transistor elements and FIG. 3 illustrates that the first transistor Q1 and the second transistor Q2 both are adjustable transistors, but the instant disclosure is not limited thereto. That is, in accordance with actual requirements, the adjustable inductor 10 also may be designed such that one of the first transistor Q1 and the second transistor Q2 is a single transistor element, while the other is an adjustable transistor.

Refer to FIG. 1A and FIG. 4. In some embodiments, in addition to the first transistor Q1 and the first current source I1 mentioned above, the first transductor 11 may further include a resistor R1 and another transistor Q3 (hereinafter called as a third transistor Q3). The resistor R1 is electrically connected between the second node N2 and the control terminal of the second transistor Q2. In other words, a first end of the resistor R1 is electrically connected to the first current source I1, and a second end of the resistor R1 is electrically connected to the control terminal of the second transistor Q2. That is, one of two ends of the resistor R1 and the first current source I1 are coupled to each other at the second node N2, and the other end of the resistor R1 and the control terminal of the second transistor Q2 are coupled to each other at the another node N3. Herein, the control terminal of the second transistor Q2 receives the offset voltage Vb2 (i.e., the terminal voltage of the second node N2) through the transistor R1. In other words, the offset voltage Vb2 is lowered by the resistor R1 to form the offset voltage Vb2′, and the working region of the second transistor Q2 is controlled through this offset voltage Vb2′.

The input terminal of the third transistor Q3 is electrically connected to the second node N2, the control terminal of the third transistor Q3 is electrically connected to (receives) an offset voltage Vb3, and the output terminal of the third transistor Q3 is electrically connected to the input terminal of the first transistor Q1. In other words, the input terminal of the third transistor Q3 is electrically connected to the first current source I1 and the first end of the resistor R1. Herein, the offset voltage Vb3 if configured to control the working region of the third transistor Q3.

The working region of the third transistor Q3 and the resistance value of the resistor R1 are also related to the value of the input impedance Zin1 of the adjustable inductor 10. Herein, the user may further change the value of the input impedance Zin1 of the adjustable inductor 10 through adjusting the offset voltage Vb3 of the third transistor Q3.

In some embodiments, the resistor R1 may be the fixed value resistance having a fixed resistance value. In alternative embodiments, the resistor R1 may also be a variable resistor having adjustment function of resistance value. At this time, the user may further change the value of the input impedance Zin1 of the adjustable inductor 10 through adjusting the resistance value of the resistor R1.

It should be noted that the capacitive impedance Zc shown in FIG. 1A may be provided by the parasitic capacitor Cgs3 of the second transistor Q2 and the parasitic capacitor Cgs4 of the third transistor Q3 shown in FIG. 4, so that the output terminal of the adjustable inductor 10 has the capacitive impedance Zc.

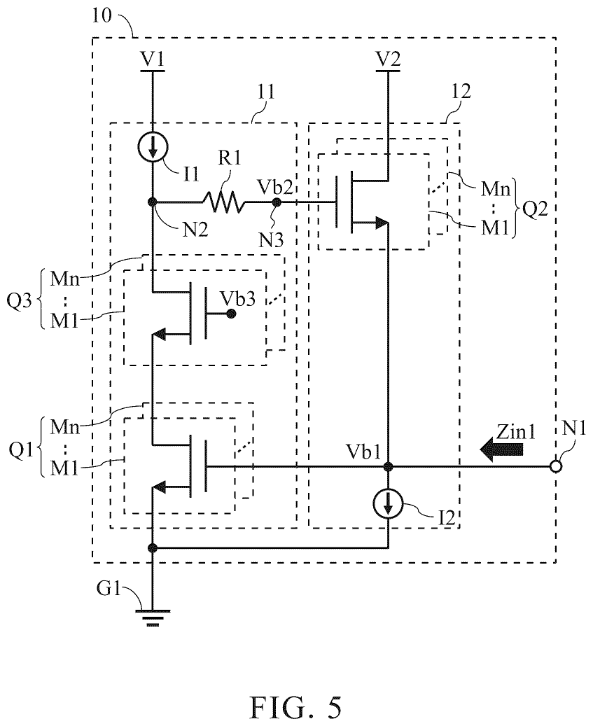

In some embodiments, the third transistor Q3 may be single transistor element, as shown in FIG. 4. In alternative embodiments, the third transistor Q3 also may be an adjustable transistor. Take FIG. 5 as an example. In this embodiment, the third transistor Q3 may be an adjustable transistor implemented by n transistor elements M1-Mn, wherein n is a positive integer greater than 1. Herein, the value of the input impedance Zin1 is further related to a size of the third transistor Q3. At this time, the user may also change the value of the input impedance Zin1 of the adjustable inductor 10 through adjusting the number of the transistor elements M1-Mn used for the third transistor Q3.

It should be understood that although FIG. 4 illustrates a scenario where the first transistor Q1, the second transistor Q2 and the third transistor Q3 are each a single transistor element, and FIG. 5 illustrates a scenario where the first transistor Q1, the second transistor Q2 and the third transistor Q3 are each an adjustable transistor, but the instant disclosure is not limited thereto. That is, in accordance with actual requirements, the adjustable inductor 10 also may be designed such that at least one of the first transistor Q1, the second transistor Q2, and the third transistor Q3 is single transistor element, while the remaining transistors are adjustable transistors.

In some embodiments, when at least two of the first transistor Q1, the second transistor Q2, and the third transistor Q3 are adjustable transistors, these adjustable transistors may be implemented by identical numbers of transistor elements M1-Mn or may be implemented by different numbers of transistor elements M1-Mn. In alternative embodiments, when the first transistor Q1, the second transistor Q2, and the third transistor Q3 are all adjustable transistors, two of the adjustable transistors are implemented using identical numbers of transistor elements M1-Mn, while the remaining adjustable transistor is implemented by different number of transistor elements M1-Mn.

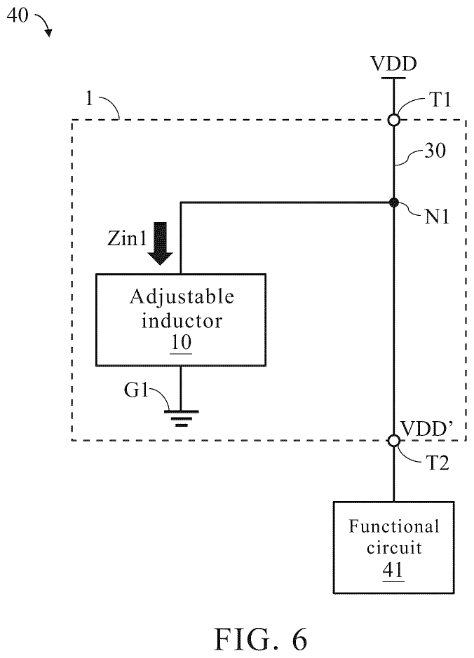

Refer to FIG. 6 to FIG. 9. In some embodiments, the adjustable inductor 10 of any the aforementioned embodiments may be applied to a filter circuit 1. In other words, the filter circuit 1 at least includes the adjustable inductor 10 of any of the aforementioned embodiments. For example, the filter circuit 1 shown in any figure of FIG. 6 to FIG. 9 at least includes the adjustable inductor 10 shown in any figure of FIG. 1A, FIG. 1B and FIG. 2 to FIG. 5.

Refer to FIG. 6 to FIG. 9. In some embodiments, the filter circuit 1 includes a power terminal T1, the adjustable inductor 10, and an output terminal T2. The adjustable inductor 10 is electrically connected between the power terminal T1 and the ground terminal G1, and the output terminal T2 is electrically connected to the power terminal T1 and the adjustable inductor 10. The power terminal T1 and the output terminal T2 are electrically connected to the first node N1. In other words, the power terminal T1 and the output terminal T2 are electrically connected to the control terminal of the first transistor Q1, the output terminal of the second transistor Q2, and one of two ends of the second current source I2 in the adjustable inductor 10.

Herein, the power terminal T1 is configured to receive an operation power VDD. The adjustable inductor 10 is configured to eliminate noise on a power wiring 30 between the power terminal T1 and the output terminal T2 to generate an operation power VDD′. The output terminal T2 is configured to output the operation power VDD′ after the noise is eliminated.

Refer to FIG. 2 to FIG. 9. In some embodiments, the voltage value of the first power source V1 and the voltage value of the second power source V2 are both less than the voltage value of the operation power VDD. Herein, the voltage value of the first power source V1 and the voltage value of the second power source V2 are each for example 1 Volt or 3 Volts, but the instant disclosure is not limited thereto. In addition, the voltage value of the operation power VDD is for example 5 Volts, 10 Volts, or 12 Volts, but the instant disclosure is not limited thereto. Because the filter circuit 1 does not need a power source with a high voltage (for example, but not limited to, 12 Volts) to be driven, that, the voltage value of the first power source V1 and the voltage value of the second power source V2 which drive the filter circuit 1 are set to be less than the voltage value of the operation power VDD, can effectively reduce the power consumption of the filter circuit 1. Therefore, the user may eliminate the noise in the circuit system through the filter circuit 1 with low power consumption.

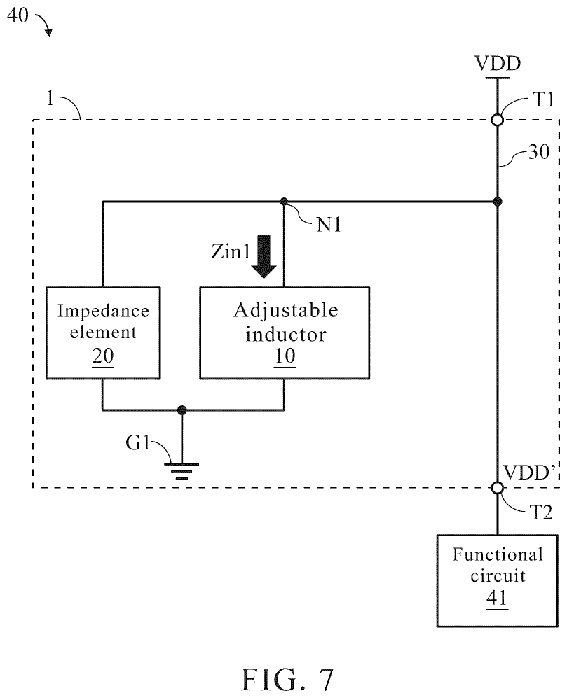

Refer to FIG. 7 to FIG. 9. In some embodiments, the filter circuit 1 further includes an impedance element 20. The impedance element 20 may be arranged at different positions in the filter circuit 1 in accordance with actual requirements, so as to form filters of different forms with the adjustable inductor 10.

Take FIG. 7 as an example. In this embodiment, the impedance element 20 is connected to the adjustable inductor 10 in parallel. In other words, one of two ends of the impedance element 20 is electrically connected to the first node N1, and the other end of the impedance element 20 is electrically connected to the ground terminal G1. Herein, the circuit combination formed by the adjustable inductor 10 and the impedance element 20 may be considered a band-pass filter.

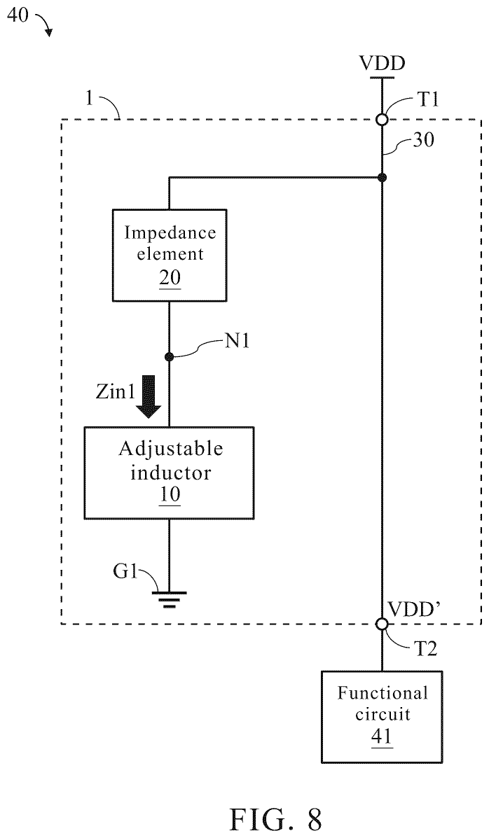

Take FIG. 8 as another example. In this embodiment, one of two ends of the impedance element 20 is electrically connected to the power terminal T1 and the output terminal T2, and the other end of the impedance element 20 is electrically connected to the adjustable inductor 10. In other words, the other end of the impedance element 20 is electrically connected to the first node N1. Herein, the circuit combination formed by the adjustable inductor 10 and the impedance element 20 may be considered a band-stop filter.

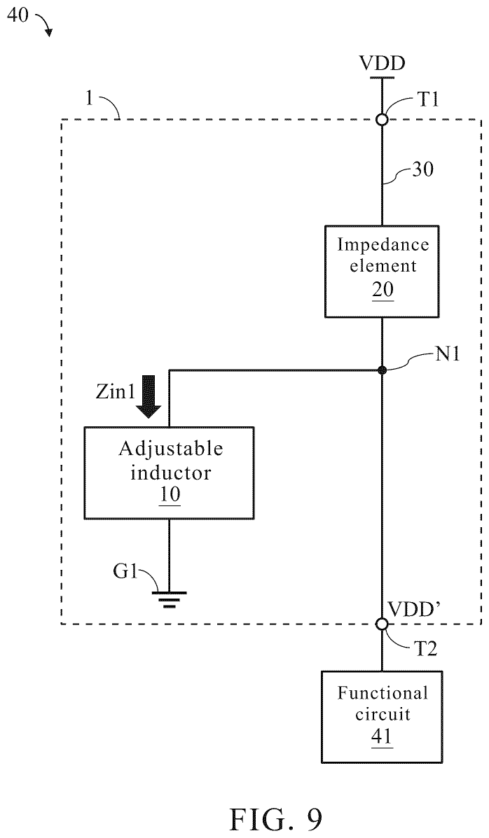

Take FIG. 9 as another example. In this embodiment, one of two ends of the impedance element 20 is electrically connected to the power terminal T1, and the other end of the impedance element 20 is electrically connected to the adjustable inductor 10 and the output terminal T2. In other words, the other end of the impedance element 20 is electrically connected to the first node N1 and the output terminal T2. Herein, the circuit combination formed by the adjustable inductor 10 and the impedance element 20 may be considered a high-pass filter.

In some embodiments, the impedance element 20 may be single hardware element having an impedance value. In alternative embodiments, the impedance element 20 may be a circuit consisting of a plurality of hardware elements having impedance values. For example, the impedance element 20 may be, but not limited to, a resistor, a capacitor, or a circuit made of a resistor and a capacitor (hereinafter called as an RC circuit). In an exemplary embodiment, when the impedance element 20 is a resistor, the impedance element 20 and the adjustable inductor 10 form an RL circuit. In another exemplary embodiment, when the impedance element 20 is a capacitor, the impedance element 20 and the adjustable inductor 10 form an LC circuit. In yet another exemplary embodiment, when the impedance element 20 is an RC circuit, the impedance element 20 and the adjustable inductor 10 form an RLC circuit. In some embodiments, the user may also change the frequencies filtered by the filter circuit 1 through adjusting the inductance of the adjustable inductor 10.

Refer to FIG. 6 to FIG. 9. In some embodiments, the filter circuit 1 of any of the aforementioned embodiments may be applied to a circuit system 40 of any type to eliminate noise on the power wiring 30 of the circuit system 40. As a result, the stability of the circuit system 40 is increased. Specifically, the power terminal T1 of the filter circuit 1 serves as the power terminal of the circuit system 40, while the output terminal T2 of the filter circuit 1 serves as the power-supplying terminal of a functional circuit 41 of the circuit system 40. That is, the power wiring 30 of the filter circuit 1 replaces the wiring between the power terminal of the circuit system 40 and the power-supplying terminal of functional circuit 41, so that the filter made of the adjustable inductor 10 of any of the embodiments is connected to the power wiring 30 of the circuit system 40 in parallel. Herein, the filter can eliminate noise coupled from an unknown path onto the filter (for example, noise of unknown frequencies transmitted to the power wiring 30 through the coupling between metal elements and/or traces in the circuit). In addition, the frequencies filtered by the filter can be adjusted by adjusting the inductance of the adjustable inductor 10.

Refer to FIG. 6 to FIG. 9. Take the example where the filter circuit 1 is disposed in radio-frequency system. That is, in this embodiment, the circuit system 40 is the radio-frequency system. The power terminal T1 of the filter circuit 1 is electrically connected to the power terminal of the radio-frequency system, and the output terminal T2 of the filter circuit 1 is electrically connected to the power-supplying terminal of a radio-frequency chip (i.e., the functional circuit 41) of the radio-frequency system. In response to that the radio-frequency system starts operation, i.e., an external power supply circuit (not shown in the drawings) applies an operation power VDD to the power terminal of the radio-frequency system, the radio-frequency system receives the operation power VDD from the external power source supply circuit (not shown in the drawings) through the power terminal T1 in the filter circuit 1, and the radio-frequency chip receives the operation power VDD′ through the output terminal T2 in the filter circuit 1 after the noise is eliminated. Herein, the operation power VDD′ acts as the power needed for operation of the radio-frequency (for example, for executing a wireless communication function).

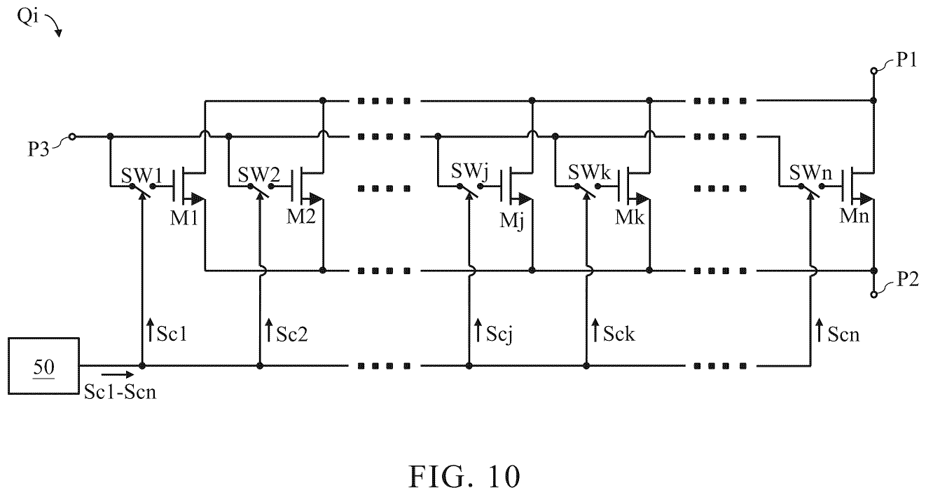

Refer to FIG. 10. In some embodiments, the adjustable transistor Qi includes a plurality of transistor elements M1-Mn, a plurality of switches SW1-SWn, and a selection circuit 50. These transistor elements M1-Mn are connected between a first connection point P1 and a second connection point P2 in parallel, and the control terminals of the transistor elements M1-Mn are respectively coupled to a third connection point P3 through switches SW1-SWn. The control terminals of the switches SW1-SWn are coupled to the selection circuit 50 and are controlled by the selection circuit 50. In other words, the input terminal of each transistor element M1/M2/ . . . /Mn is coupled to the first connection point P1, and the output terminal of each transistor element M1/M2/ . . . /Mn is coupled to the second connection point P2. The transistor elements M1-Mn correspond to the switches SW1-SWn in a one-by-one manner. A first end of each of the switches SW1/SW2/ . . . /SWn is coupled to the control terminal of a corresponding one of the transistor elements M1/M2/ . . . /Mn. A second end of each switch SW1/SW2/ . . . /SWn is coupled to the third connection point P3. The control terminal of each switch SW1/SW2/ . . . /SWn is coupled to the selection circuit 50. The selection circuit 50 is configured to generate a set of control signals Sc1-Scn to control the operation of the switches SW1-SWn and thereby modulate the value of the input impedance Zin1 of the adjustable inductor 10. When the adjustable transistor Q1/Q2/Q3 is applied to the adjustable inductor 10, the first connection point P1 is coupled to a front-stage circuit (for example, the second node N2, a power source V2, or the transistor Q3), the second connection point P2 is coupled to a back-stage circuit (for example, the ground terminal G1, the first node N1, or the transistor Q1), and the third connection point P3 is electrically connected to the offset voltage Vb1/Vb2/Vb2′/Vb3, wherein, i is 1, 2, or 3.

Specifically, when the adjustable transistor Qi is the first transistor Q1 shown in FIG. 3, the first connection point P1 is the input terminal of the first transistor Q1, the second connection point P2 is the output terminal of the first transistor Q1, and the third connection point P3 is the control terminal of the first transistor Q1. Refer to FIG. 3 and FIG. 10. The first connection point P1, the first current source I1, and the control terminal of the second transistor Q2 are commonly coupled to the second node N2. The second connection point P2 is coupled to the ground terminal G1. The third connection point P3, the second current source I2, and the output terminal of the second transistor Q2 are commonly coupled to the first node N1. Herein, the third connection point P3 is configured to receive the offset voltage Vb1, i.e., the terminal voltage of the first node N1.

When the adjustable transistor Qi is the second transistor Q2 shown in FIG. 3, the first connection point P1 is the input terminal of the second transistor Q2, the second connection point P2 is the output terminal of the second transistor Q2, and the third connection point P3 is the control terminal of the second transistor Q2. Refer to FIG. 3 and FIG. 10. The first connection point P1 is coupled to the power source supply circuit (not shown in the drawings) and is configured to receive the power source V2. The second connection point P2, the second current source I2, and the control terminal of the first transistor Q1 are commonly coupled to the first node N1. The third connection point P3, the first current source I1, and the input terminal of the first transistor Q1 are commonly coupled to the second node N2. Herein, the third connection point P3 is configured to receive the offset voltage Vb2, i.e., the terminal voltage of the second node N2.

When the adjustable transistor Qi is the first transistor Q1 shown in FIG. 5, the first connection point P1 is the input terminal of the first transistor Q1, the second connection point P2 is the output terminal of the first transistor Q1, and the third connection point P3 is the control terminal of the first transistor Q1. Refer to FIG. 5 and FIG. 10. The first connection point P1 is coupled to the output terminal of the third transistor Q3. The second connection point P2 is coupled to the ground terminal G1. The third connection point P3, the second current source I2, and the output terminal of the second transistor Q2 are commonly coupled to the first node N1. Herein, the third connection point P3 is configured to receive the offset voltage Vb1, i.e., the terminal voltage of the first node N1.

When the adjustable transistor Qi is the second transistor Q2 shown in FIG. 5, the first connection point P1 is the input terminal of the first transistor Q1, the second connection point P2 is the output terminal of the first transistor Q1, and the third connection point P3 is the control terminal of the first transistor Q1. Refer to FIG. 5 and FIG. 10. The first connection point P1 is coupled to the power source supply circuit (not shown in the drawings) and is configured to receive the power source V2. The second connection point P2, the second current source I2, and the control terminal of the first transistor Q1 are commonly coupled to the first node N1. The third connection point P3 is coupled to the resistor R1. Herein, the third connection point P3 is configured to receive the offset voltage Vb2′, i.e., the terminal voltage of the second end of the resistor R1.

When the adjustable transistor Qi is the third transistor Q3 shown in FIG. 5, the first connection point P1 is the input terminal of the third transistor Q3, the second connection point P2 is the output terminal of the third transistor Q3, and the third connection point P3 is the control terminal of the third transistor Q3. Refer to FIG. 5 and FIG. 10. The first connection point P1, the first current source I1, and the first end of the resistor R1 are commonly coupled to the second node N2. The second connection point P2 is coupled to the input terminal of the first transistor Q1. The third connection point P3 is coupled to a bias generation circuit (not shown in the drawings) and is configured to receive the offset voltage Vb3.

Refer to FIG. 3, FIG. 5, and FIG. 10. Under the condition where the adjustable transistor Qi is applied to the adjustable inductor 10, when the adjustable inductor 10 operates, each of the control signals Sc1-Scn generated by the selection circuit 50 is inputted to the control terminal of a corresponding one of the switches SW1-SWn in a one-by-one manner, so that the switches SW1-SWn are turned on or turned off in response to corresponding control signals Sc1-Scn. In other words, an expected number (take j as an example) of the switches SW1-SWj among the switches SW1-SWn are turned on in response to corresponding control signals Sc1-Scj. As a result, corresponding transistor elements M1-Mj respectively receive the offset voltages Vb1/Vb2/Vb2′/Vb3 through the switches SW1-SWj and operate accordingly. The rest of the switches SWk-SWn are turned off in response to corresponding control signals Sck-Scn. As a result, corresponding transistor elements Mk-Mn cannot receive the offset voltages Vb1/Vb2/Vb′/Vb3 through corresponding switches SWk-SWn and are thus disabled. Accordingly, the modulation of the value of the input impedance Zin1 of the adjustable inductor 10 can be achieved. In this embodiment, j is any positive integer of 1-n, and k is j+1.

In some embodiments, each aforementioned transistor element (for example, the transistors Q1-Q3 implemented using the single transistor elements or the transistor elements M1-Mn in the adjustable transistor Qi) may be a transistor of any type, such as, but not limited to, a bipolar junction transistor (BJT) and a metal oxide semiconductor field effect transistor (MOSFET). Take MOSFET as an example, the input terminal of the transistor element is a drain, the output terminal of the transistor element is a source, and the control terminal of the transistor element is a gate. Take BJT as another example, the input terminal of the transistor element is a collector, the output terminal of the transistor element is an emitter, and the control terminal of the transistor element is a base. In some embodiments, when the transistor elements M1-Mn of the transistor Q1/Q2/Q3 are bipolar junction transistors, the working region of the transistor Q1/Q2/Q3 include a cut-off region, a saturation region, and an active region. In alternative embodiments, when the transistor elements M1-Mn the transistor Q1/Q2/Q3 are implemented by a metal oxide semiconductor field effect transistor, the working regions of the transistor Q1/Q2/Q3 include a cut-off region, a linear region, and a saturation region.

As above, according to any embodiment, the filter circuit 1 or the adjustable inductor 10 is able to implement the inductor (i.e., the adjustable inductor 10) having adjustment function of inductance through a small number of hardware elements, thereby effectively adjusting the inductance, and simultaneously avoiding and solving problems such as floor-planning area being too large and quality factor (also called as a “Q value”) being not enough. Herein, the filter circuit 1 implemented by the adjustable inductor 10 is able to effectively eliminate noise on the power wiring 30 of the circuit system to which the filter circuit 1 is applied by adjusting the inductance of the adjustable inductor 10, thereby improving the stability of the circuit system. In addition, through changing a parameter of each hardware element (for example, the transistor Q1/Q2/Q3) in the adjustable inductor 10, the cost, the size, and the power consumption of the adjustable inductor 10 can be effectively reduced, such that the quality factor of the adjustable inductor 10 is increased. Furthermore, according to some embodiments, depending on configuration position of an impedance element 20, the impedance element 20 and the adjustable inductor 10 can form the filter circuits 1 with different circuit combinations, thereby implementing various types of filters.

Although the instant disclosure has been disclosed using the exemplary embodiments above, the exemplary embodiments are not meant to limit the instant disclosure. Any alteration and retouch made by persons skilled in the art without deviating from the spirit of the instant disclosure shall fall into the scope of the instant disclosure.

What is claimed is:

1. A filter circuit comprising:
a power terminal, configured to receive an operation power;
an output terminal, configured to output the operation power;
a power wiring, coupled between the power terminal and the output terminal; and
an adjustable inductor, electrically connected between the power wiring and a ground terminal, configured to eliminate noise on the power wiring.

2. The filter circuit according to claim 1, wherein the adjustable inductor comprises:
a first transductor, an input terminal of the first transductor is electrically connected to the power terminal; and
a second transductor, an output terminal of the second transductor is electrically connected to the input terminal of the first transductor, and an input terminal of the second transductor is electrically connected to an output terminal of the first transductor.

3. The filter circuit according to claim 2, wherein the first transductor comprises:
a first current source, electrically connected between a first power source and a node; and
a first transistor, an input terminal of the first transistor is electrically connected to the node, a control terminal of the first transistor is electrically connected to the power terminal, and an output terminal of the first transistor is electrically connected to the ground terminal; and
wherein the second transductor comprises:
a second transistor, an input terminal of the second transistor is electrically connected to a second power source, a control terminal of the second transistor is electrically connected to the node, and an output terminal of the second transistor is electrically connected to the power terminal; and
a second current source, electrically connected between the power terminal and the ground terminal.

4. The filter circuit according to claim 3, wherein the first transistor is an adjustable transistor, and/or the second transistor is another adjustable transistor.

5. The filter circuit according to claim 3, wherein the first transistor is single transistor element, and/or the second transistor is another single transistor element.

6. The filter circuit according to claim 3, wherein a voltage value of the first power source and a voltage value of the second power source are both less than a voltage value of the operation power.

7. The filter circuit according to claim 3, wherein the first transductor further comprises:
a resistor, electrically connected between the node and the control terminal of the second transistor; and
a third transistor, an input terminal of the third transistor is electrically connected to the node, a control terminal of the third transistor is electrically connected to an offset voltage, and an output terminal of the third transistor is electrically connected to the input terminal of the first transistor.

8. The filter circuit according to claim 7, wherein the third transistor is an adjustable transistor.

9. The filter circuit according to claim 7, wherein the third transistor is single transistor element.

10. The filter circuit according to claim 1, further comprising: an impedance element, connected to the adjustable inductor in parallel.

11. The filter circuit according to claim 1, further comprising an impedance element, wherein one of two ends of the impedance element is electrically connected to the power wiring, and the other end of the impedance element is electrically connected to the adjustable inductor.

12. The filter circuit according to claim 1, further comprising an impedance element, wherein one of two ends of the impedance element is electrically connected to the power terminal, and the other end of the impedance element is electrically connected to the adjustable inductor and the output terminal.

13. An adjustable inductor comprising:
a first transductor; and
a second transductor, electrically connected between two ends of the first transductor, wherein the first transductor and the second transductor have inverted transconductance phases.

14. The adjustable inductor according to claim 13, wherein the first transductor comprises:
a first transistor, an input terminal of the first transistor is electrically connected to a node, a control terminal of the first transistor is electrically connected to another node, and an output terminal of the first transistor is electrically connected to a ground terminal; and
a first current source, electrically connected between a first power source and the node; and
wherein the second transductor comprises:
a second transistor, an input terminal of the second transistor is electrically connected to a second power source, a control terminal of the second transistor is electrically connected to the node, and an output terminal of the second transistor is electrically connected to the another node; and
and a second current source, electrically connected between the another node and the ground terminal.

15. The adjustable inductor according to claim 14, wherein the first transistor and the second transistor are adjustable transistors.

16. The adjustable inductor according to claim 14, wherein the first transistor is single transistor element, and the second transistor is another single transistor element.

17. The adjustable inductor according to claim 14, wherein the first transductor further comprises:
a resistor, electrically connected between the node and the control terminal of the second transistor; and
a third transistor, an input terminal of the third transistor is electrically connected to the node, a control terminal of the third transistor is electrically connected to an offset voltage, and an output terminal of the third transistor is electrically connected to the input terminal of the first transistor.

18. The adjustable inductor according to claim 17, wherein the third transistor is an adjustable transistor.

19. The adjustable inductor according to claim 17, wherein the third transistor is single transistor element.
